(19) United States
(12) Patent Application Publication
(10) Pub. No.: US 2026/0255498 A1
(43) Pub. Date: Aug. 27, 2026

(54) CIRCUIT BOARD ASSEMBLY AND METHOD OF MANUFACTURING THE SAME

(71) Applicants: HongQiSheng Precision Electronics (QinHuangdao) Co., Ltd., Hebei Province (CN); Avary Holding (Shenzhen) Co., Ltd., Shenzhen (CN); Garuda Technology Co., Ltd., New Taipei City (TW)

(72) Inventors: Yuan-Yu LIN, Hebei Province (CN); Jia-Hui WANG, Hebei Province (CN)

(21) Appl. No.: 19/061,026

(22) Filed: Feb. 24, 2025

(51) Int. Cl. H05K 3/30; H05K 1/18

(52) U.S. Cl. CPC H05K 3/301; H05K 1/185; H05K 2201/09072; H05K 2201/10462; H05K 2201/10477; H05K 2201/10515; H05K 2201/1053; H05K 2201/10863

(57) ABSTRACT

A circuit board assembly includes a circuit board, an electronic component stack structure disposed in the circuit board, first and second conductive pillars. The circuit board includes first and second connection wiring layers. The electronic component stack structure has a sidewall and includes first and second electronic components. The first and second conductive pillars are disposed on the sidewall and extend in a first direction away from the sidewall. The first conductive pillar is electrically connected to the first electronic component and the first connection wiring layer. The second conductive pillar is electrically connected to the second electronic component and the second connection wiring layer. In the first direction, the distance between the first connection wiring layer and the sidewall is smaller than the distance between the second connection wiring layer and the sidewall, and the first conductive pillar is shorter than the second conductive pillar.

### BACKGROUND

### Field of Invention

The present disclosure relates to a circuit board assembly and a method of manufacturing the same.

### Description of Related Art

With the advancement of technology, the market's requirements for miniaturization, high frequency, high speed and multi-function of electronic products are also increasing. Therefore, how to arrange multiple chips in a circuit board to achieve high frequency, high speed and multi-function requirements while meeting the demand for miniaturization is one of the research goals in this technical field.

### SUMMARY

At least one embodiment of the present disclosure provides a circuit board assembly that can reduce the fan-out space of electronic components, thereby achieving the demand for miniaturization of the overall size of the circuit board assembly.

At least another embodiment of the present disclosure provides a method of manufacturing the abovementioned circuit board assembly to help the above-mentioned circuit board assembly reduce the fan-out space of electronic components, thereby achieving the demand for miniaturization of the overall size of the circuit board assembly.

The method of manufacturing the circuit board assembly according to at least one embodiment of the present disclosure includes the following steps. An electronic component stacking structure is provided, and the electronic component stacking structure has a sidewall. A base is provided, and the base has a surface and a hole. The electronic component stacking structure is disposed in the hole. After the electronic component stacking structure is disposed in the hole, a photoresist layer is attached to the surface. A first opening and a second opening exposing the sidewall are formed in the photoresist layer. A first conductive pillar is formed in the first opening, and a first conductive portion is formed in the second opening. After the first conductive pillar and the first conductive portion are formed, a second conductive portion is formed in the second opening connected to the first conductive portion to form a second conductive pillar, where the first conductive pillar and the second conductive pillar are connected to the sidewall, and a length of the second conductive pillar is greater than a length of the first conductive pillar. An initial circuit board is provided, and the initial circuit board has a stepped opening and includes a first connection wiring layer and a second connection wiring layer. The electronic component stacking structure, the first conductive pillar and the second conductive pillar are disposed in the stepped opening, the first conductive pillar is electrically connected to the first connection wiring layer, and the second conductive pillar is electrically connected to the second connection wiring layer.

The circuit board assembly according to at least another embodiment of the present disclosure includes a circuit board, an electronic component stacking structure, a first conductive pillar and a second conductive pillar. The circuit board includes a first connection wiring layer and a second connection wiring layer disposed on the first connection wiring layer. The electronic component stacking structure is disposed in the circuit board, has a sidewall, and includes a first electronic component electrically connected to the first connection wiring layer, and a second electronic component disposed on the first electronic component and electrically connected to the second connection wiring layer. The first conductive pillar is disposed on the sidewall, extends in a first direction away from the sidewall, and is electrically connected to the first electronic component and the first connection wiring layer. The second conductive pillar is disposed on the sidewall, extends in the first direction, and is electrically connected to the second electronic component and the second connection wiring layer. In the first direction, the distance between the first connection wiring layer and the sidewall is smaller than the distance between the second connection wiring layer and the sidewall, and the length of the first conductive pillar is smaller than the length of the second conductive pillar.

It is to be understood that both the foregoing general descriptions and the following detailed descriptions are by examples, and are intended to provide further explanation of the present disclosure as claimed.

### BRIEF DESCRIPTION OF THE DRAWINGS

The present disclosure can be more fully understood by reading the following detailed description of the embodiments, with reference made to the accompanying drawings as follows:

FIG. 1 is a partial schematic cross-sectional view of a circuit board assembly according to at least one embodiment of the present disclosure.

FIGS. 2A to 2Q are partial schematic cross-sectional views of the circuit board assembly as shown in FIG. 1 at different manufacturing stages.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

In the following description, in order to clearly present the technical features of the present disclosure, the dimensions (such as length, width, thickness, and depth) of elements (such as layers, films, bases, and areas) in the drawings will be enlarged in unequal proportions. Therefore, the description and explanation of the following embodiments are not limited to the sizes and shapes presented by the elements in the drawings, but should cover the sizes, shapes, and deviations of the two due to actual manufacturing processes and/or tolerances.

Furthermore, the words “about”, “approximately” or “substantially” used in the present disclosure not only cover the clearly stated numerical values and numerical ranges, but also cover those that can be understood by a person with ordinary knowledge in the technical field to which the present disclosure belongs. The permissible deviation range can be determined by the error generated during measurement, and the error is caused, for example, by limitations of the measurement system or process conditions.

The spatial relative terms used in the present disclosure, such as “below”, “under”, “above”, “on”, and the like, are intended to facilitate the recitation of a relative relationship between one element or feature and another as depicted in the figures. The true meaning of these spatial relative terms includes other orientations. For example, the relationship between one element and another may change from “below” and “under” to “above” and “on” when the figure is turned 180 degrees up or down.

It should be understood that while the present disclosure may use terms such as “first”, “second”, “third”, etc. to describe various elements or features, these elements or features should not be limited by these terms. These terms are primarily used to distinguish one element from another, or one feature from another. In addition, the term “or” as used in the present disclosure may include, as appropriate, any one or a combination of the listed items in association.

Although a series of operations or steps are used to illustrate the manufacturing method in the present disclosure, the order shown in these operations or steps should not be construed as a limitation of the present disclosure.

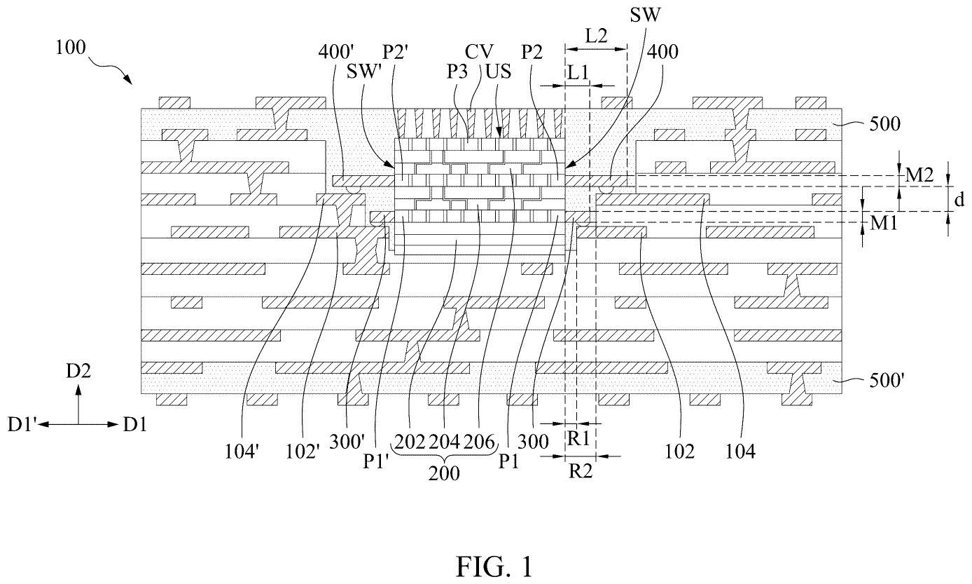

FIG. 1 is a partial schematic cross-sectional view of a circuit board assembly 10 according to at least one embodiment of the present disclosure. The circuit board assembly 10 includes a circuit board 100, an electronic component stacking structure 200, first conductive pillars 300, 300′ and second conductive pillars 400, 400′. The circuit board 100 includes first connection wiring layers 102, 102′ and second connection wiring layers 104, 104′ disposed on the first connection wiring layers 102, 102′.

The electronic component stacking structure 200 is disposed in the circuit board 100, has side walls SW, SW′, and includes a first electronic component 202 and a second electronic component 204. The first electronic component 202 is electrically connected to the first connection wiring layers 102, 102′, and the second electronic component 204 is disposed on the first electronic component 202 and electrically connected to the second connection wiring layers 104, 104′. The first conductive pillars 300, 300′ are disposed on the sidewalls SW, SW′, extend in a first direction D1, D1′ away from the sidewalls SW, SW′, and are electrically connected to the first electronic component 202 and the first connection wiring layer. 102, 102′. The second conductive pillars 400, 400′ are disposed on the sidewalls SW, SW′ and extend in the first directions D1, D1′. The second conductive pillars 400, 400′ are disposed on the first conductive pillars 300, 300′ and are electrically connected to the second electronic component 204 and the second connection wiring layers 104, 104′.

In the first direction D1, the distance R1 between the first connection wiring layer 102 and the sidewall SW is smaller than the distance R2 between the second connection wiring layer 104 and the sidewall SW, and the length L1 of the first conductive pillar 300 is smaller than the length L2 of the second conductive pillar 400. Similarly, in the first direction D1′, the distance (not labeled) between the first connection wiring layer 102′ and the sidewall SW′ is smaller than the distance (not labeled) between the second connection wiring layer 104′ and the sidewall SW′, and the length (not labeled) of the first conductive pillar 300′ is smaller than the length (not labeled) of the second conductive pillar 400′.

Since the first electronic component 202 and the second electronic component 204 of the electronic component stacking structure 200 can be electrically connected to the first connection wiring layer 102, 102′ and the second connection wiring layer 104, 104′ at different distances from the sidewalls SW, SW′ by the first conductive pillars 300, 300′ and the second conductive pillars 400, 400′, which have different lengths and are disposed on the sidewalls SW, SW′. The fan-out space of the first electronic component 202 and the second electronic component 204 is reduced, thereby achieving the demand for miniaturization of the overall size of the circuit board assembly 10.

Referring to FIG. 1, the first electronic component 202 includes first pads P1, P1′, and the second electronic component 204 includes second pads P2, P2′. The first pads P1, P1′ and the second pads P2 and P2′ are exposed on the sidewalls SW, SW′. The first conductive pillars 300, 300′ are in contact with the first pads P1,P1′ and disposed on the first connection wiring layers 102, 102′ to electrically connect to the first electronic component 202 and the first connection wiring layers 102, 102′. The second conductive pillars 400, 400′ are in contact with the second pads P2, P2′ and disposed on the second connection wiring layers 104, 104′ to electrically connect to the second electronic component 204 and the second connection wiring layers 104, 104′.

The electronic component stacking structure 200 has an upper surface US and further includes a third electronic component 206 disposed on the second electronic component 204. The third electronic component 206 includes third pads P3 exposed on the upper surface US. The circuit board 100 further includes a build-up structure 500 disposed on the third electronic component 206. The build-up structure 500 has conductive vias CV disposed on the third pads P3 and electrically connected to the third pads P3. By the aforementioned design, the fan-out space of the third electronic component 206 can be reduced, thereby achieving the demand for miniaturization of the overall size of the circuit board assembly 10.

As shown in FIG. 1, the second connection wiring layers 104, 104′ are disposed on the first connection wiring layers 102, 102′ in a second direction D2, respectively. The second electronic component 204 is disposed on the first electronic component 202 in the second direction D2, and the third electronic component 206 is disposed on the second electronic component 204 in the second direction D2. The build-up structure 500 is disposed on the third electronic component 206 in the second direction D2. The second conductive pillars 400, 400′ are disposed on the first conductive pillars 300, 300′ in the second direction D2, respectively. That is, in the second direction D2, the second connection wiring layers 104, 104′ partially overlap with the first connection wiring layers 102, 102′, respectively. In the second direction D2, the first electronic component 202, the second electronic component 204, and the third electronic component 206 are overlapped with each other, and the first electronic component 202, the second electronic component 204, and the third electronic component 206 partially overlap with the build-up structure 500. In the second direction D2, the second conductive pillars 400, 400′ partially overlap with the first conductive pillars 300, 300′, respectively. In the second direction D2, the conductive vias CV partially overlap with the third pads P3 and are in contact with the third pads P3. The second direction D2 is substantially perpendicular to the first directions D1, D1′. The second direction D2 may be, for example, is the normal direction of the circuit board 100.

In addition, the circuit board 100 further includes a build-up structure 500′ disposed opposite to the build-up structure 500, that is, the build-up structure 500′, the electronic component stacking structure 200, and the build-up structure 500 are stacked in the second direction D2. The edge (not labeled) of the first electronic component 202, the edge (not labeled) of the second electronic component 204, and the edge (not labeled) of the third electronic component 206 are flush with each other in the second direction D2 to form the sidewalls SW, SW′ of the electronic component stacking structure 200, which can reduce the space occupied by the electronic component stacking structure 200 in the circuit board 100, thereby achieving the demand for miniaturization of the overall size of the circuit board assembly 10.

The first conductive pillar 300 and the second conductive pillar 400 are disposed on the sidewall SW at the right side of the electronic component stacking structure 200 and extend in the first direction D1 away from the sidewall SW. The first conductive pillar 300 and the second conductive pillar 400 have one end adjacent to the sidewall SW and in contact with the first pad P1 and the second pad P2 exposed on the sidewall SW, respectively. Furthermore, the first conductive pillar 300 and the second conductive pillar 400 have one end away from the sidewall SW and electrically connected to the first connection wiring layers 102 and the second connection wiring layers 104 at the right side of the electronic component stacking structure 200 through solder balls (not labeled), respectively.

The first conductive pillar 300′ and the second conductive pillar 400′ are disposed on the sidewall SW′ at the left side of the electronic component stacking structure 200 and extend in the first direction D1′ away from the sidewall SW′. The first conductive pillar 300′ and the second conductive pillar 400′ have one end adjacent to the sidewall SW′ and in contact with the first pad P1′ and the second pad P2′ exposed on the sidewall SW′, respectively. Furthermore, the first conductive pillar 300′ and the second conductive pillar 400′ have one end away from the sidewall SW′ and electrically connected to the first connection wiring layers 102′ and the second connection wiring layers 104′ at the left side of the electronic component stacking structure 200 through solder balls (not labeled), respectively.

In some embodiments, the first directions D1, D1′ are substantially 180 degrees apart. The diameter M1 of the first conductive pillar 300 and the diameter M2 of the second conductive pillar 400 are about 10 micrometers to 40 micrometers, respectively. In the first direction D1, the length L1 of the first conductive pillar 300 is about 10 micrometers to 40 micrometers, and the length L2 of the second conductive pillar 400 is about 50 micrometers to 80 micrometers. In the second direction D2, the distance d between the first conductive pillar 300 and the second conductive pillar 400 is about 10 micrometers to 50 micrometers.

Similarly, the diameter (not labeled) of the first conductive pillar 300′ and the diameter (not labeled) of the second conductive pillar 400′ are about 10 micrometers to 40 micrometers, respectively. In the first direction D1, the length (not labeled) of the first conductive pillar 300′ is about 10 micrometers to 40 micrometers, and the length (not labeled) of the second conductive pillar 400′ is about 50 micrometers to 80 micrometers. In the second direction D2, the distance (not labeled) between the first conductive pillar 300′ and the second conductive pillar 400′ is about 10 micrometers to 50 micrometers.

In some embodiments, the first electronic component 202, the second electronic component 204, and the third electronic component 206 may be chips. The material of the first connection wiring layers 102, 102′, the material of the second connection wiring layers 104, 104′, the material of the first conductive pillars 300, 300′, the material of the second conductive pillars 400, 400′, the material of the first pads P1, P1′, the material of the second pads P1, P1′, the material of the third pads P3 and the material of the conductive vias CV may include metal, such as copper. The material of the build-up structures 500, 500′ may include resin, such as low flow prepreg or no flow prepreg. In addition, the number of electronic components, the number of connection wiring layers, the number of conductive pillars, the number of pads, the number of conductive vias, and the number of solder balls are not limited to the embodiments of the present disclosure. In other embodiments, the number of the aforementioned elements may be increased or decreased according to product requirements of the circuit board assembly.

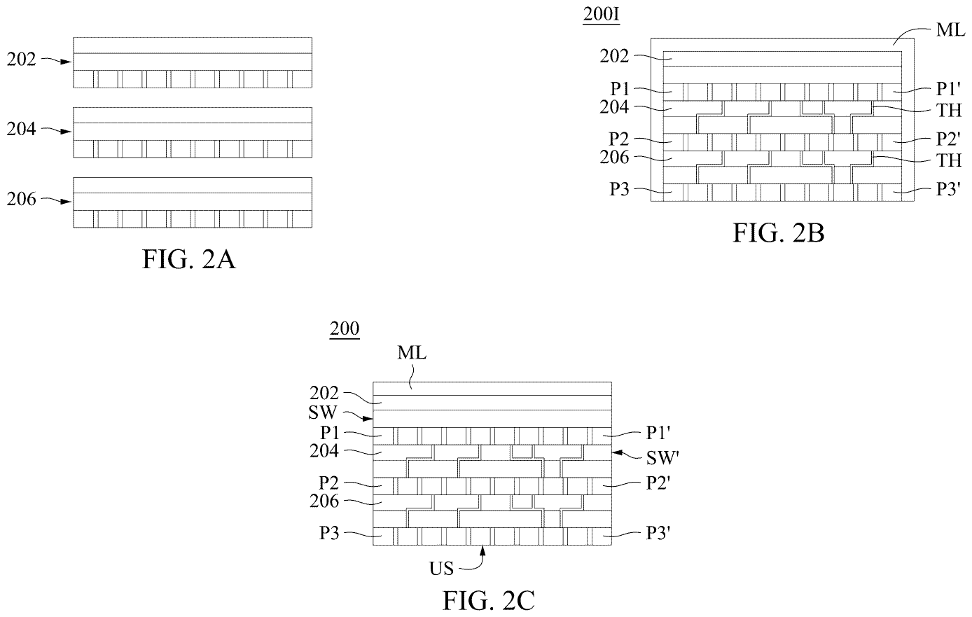

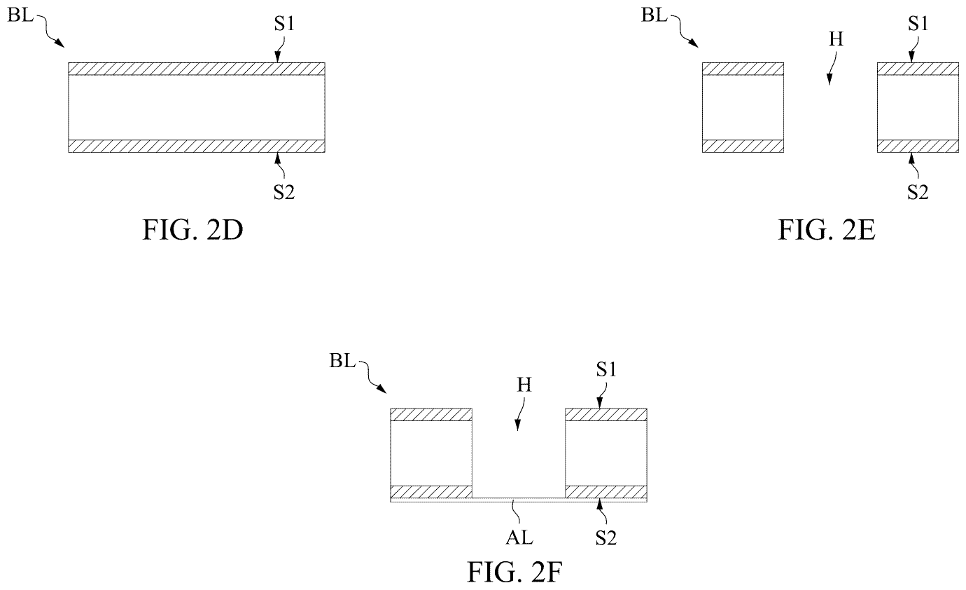

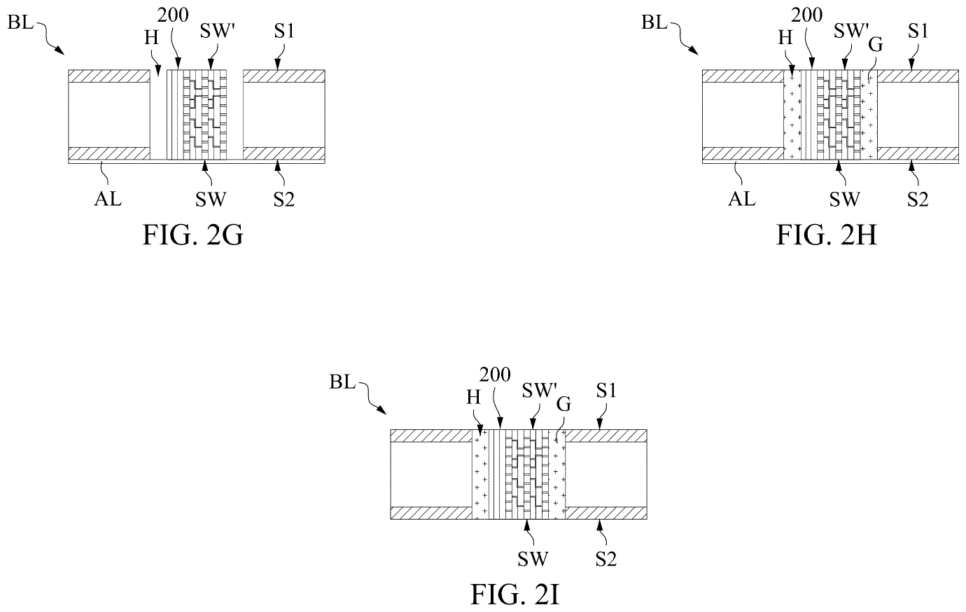

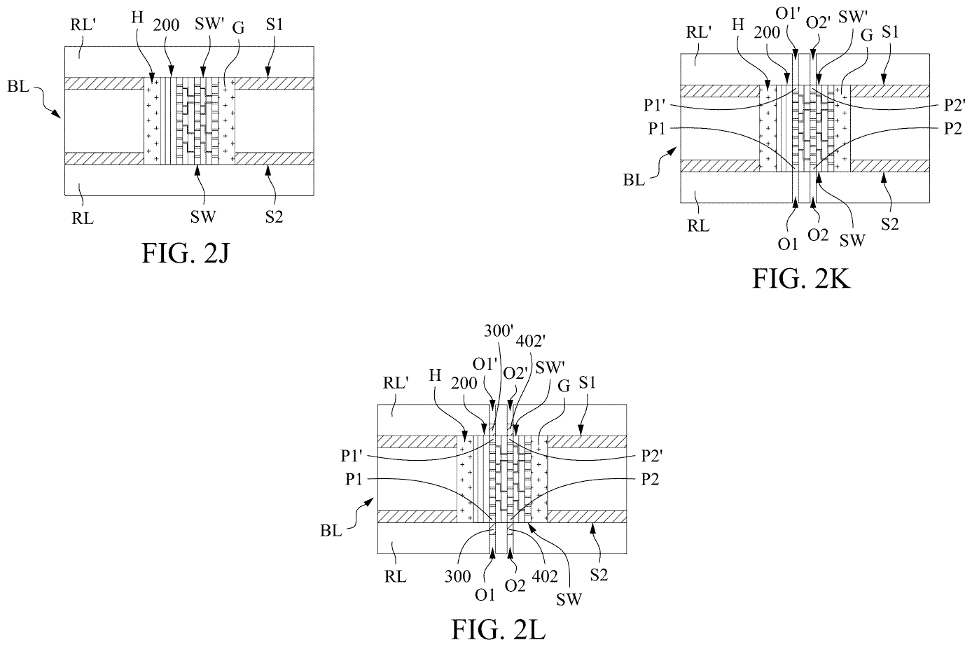

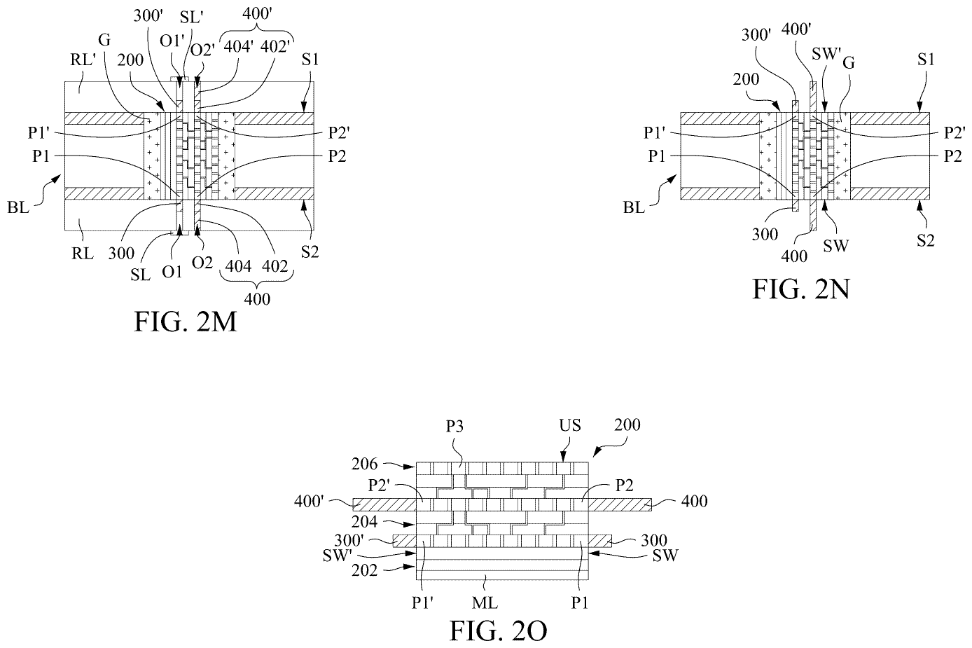

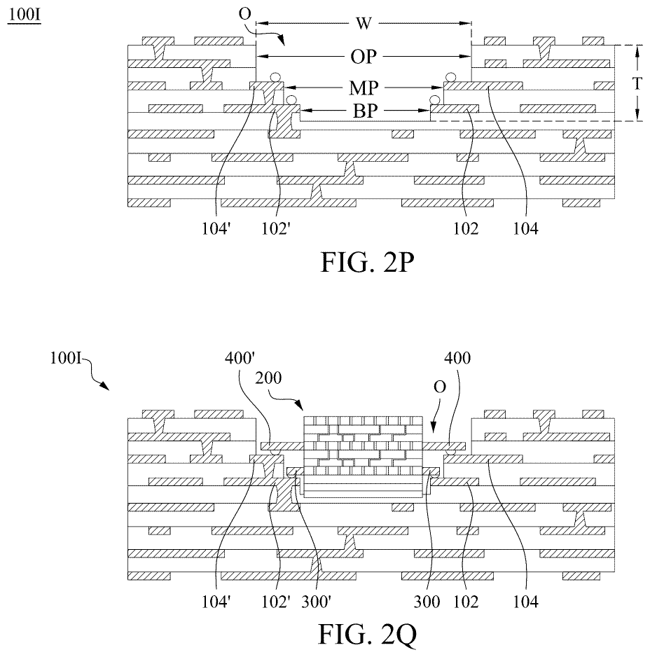

FIGS. 2A to 2Q are partial schematic cross-sectional views of the circuit board assembly 10 as shown in FIG. 1 at different manufacturing stages. First, referring to FIG. 2A and FIG. 2B, a first electronic component 202, a second electronic component 204, and a third electronic component 206 are stacked and sealed to form an initial electronic component stacking structure 200I.

In detail, as shown in FIG. 2A, the first electronic component 202, the second electronic component 204, and the third electronic component 206 are provided. As shown in FIG. 2B, the first electronic component 202, the second electronic component 204, and the third electronic component 206 are stacked, and through holes TH are formed between the first electronic component 202, the second electronic component 204, and the third electronic component 206 to electrically connected to first pads P1, P1′ of the first electronic component 202, second pads P2, P2′ of the second electronic component 204, and third pads P3 and P3′ of the third electronic component 206. The sealing layer ML is provided to seal the first electronic component 202, the second electronic component 204, and the third electronic component 206 to form the initial electronic component stacking structure 200I. In some embodiments, the material of the sealing layer ML may include resin.

Next, referring to FIG. 2C, the initial electronic component stacking structure 200I is polished to form an electronic component stacking structure 200. The electronic component stacking structure 200 has sidewalls SW, SW′. The first pads P1, P1′ of the first electronic component 202 are exposed on the sidewalls SW, SW′, and the second pads P2, P2′ of the second electronic component 204 are exposed on the sidewalls SW, SW′. In addition, the electronic component stacking structure 200 further has an upper surface US, and the third pads P3, P3′ of the third electronic component 206 are exposed on the side walls SW, SW′ and exposed on the upper surface US. In some embodiments, polishing the initial electronic component stack structure 200I may be performed by a chemical mechanical polishing (CMP) process.

Referring to FIG. 2D, a base BL is provided. The base BL has a first surface S1 and a second surface S2 opposite to the first surface S1. Referring to FIG. 2E, a hole H extending from the first surface S1 to the second surface S2 is formed. Referring to FIG. 2F, after the hole H is formed, an adhesive layer AL is attached to the second surface S2. In some embodiments, the hole H may be formed by a laser process or a machining process, such as a milling process. The material of the adhesive layer AL may include polyimide (PI).

Next, referring to FIG. 2G, the electronic component stacking structure 200 is disposed in the hole H, and the sidewall SW is in contact with the adhesive layer AL. Referring to FIG. 2H, after the electronic component stacking structure 200 is disposed in the hole H, the hole H is filled with a glue G. Referring to FIG. 2I, after the glue G is filled in the hole H, the adhesive layer AL is removed, and the sidewalls SW, SW′ are exposed by the glue G. In some embodiments, the glue G may be degradable glue.

Referring to FIG. 2J, after the adhesive layer AL is removed, photoresist layers RL′, RL are attached to the first surface S1 and the second surface S2, respectively. Referring to FIG. 2K, first openings O1, O1′ exposing the first pads P1, P1′ and second openings O2, O2′ exposing the second pads P2, P2′ are formed in the photoresist layers RL, RL′. Referring to FIG. 2L, first conductive pillars 300, 300′ are formed in the first openings O1, O1′, respectively, and first conductive portions 402, 402′ are formed in the second openings O2, O2′, respectively. In some embodiments, attaching the photoresist layers RL′, RL to the first surface S1 and the second surface S2 may be performed by a lamination process. The first openings O1, O1′ and the second openings O2, O2′ may be formed by an exposure and development process.

Referring to FIG. 2M, after the first conductive pillars 300, 300′ and the first conductive portions 402, 402′ are formed, masking layers SL, SL′ are attached to the first openings O1, O1′ to cover the first openings O1, O1′. After attaching the masking layers SL and SL′ to the first openings O1, O1′, second conductive portions 404, 404′ are formed in the second openings O2, O2′, respectively, and the second conductive portions 404, 404′ are connected to the first conductive portions 402, 402′ to form second conductive pillars 400, 400′, respectively. Since the second conductive pillars 400 and 400′ are formed by connecting the first conductive portions 402, 402′ and the second conductive portions 404, 404′, there is a boundary (not labeled) between the first conductive portions 402, 402′ and the second conductive portions 404, 404′. In some embodiments, the material of the masking layers SL, SL′ may include polyimide. The first conductive pillars 300, 300′, the first conductive portions 402, 402′ and the second conductive portions 404, 404′ may be formed by an electroplating process.

Referring to FIG. 2N and FIG. 2O, after the second conductive pillars 400, 400′ are formed, the masking layers SL, SL′, the photoresist layers RL, RL′, the glue G and the base BL are removed. First, as shown in FIG. 2N, the masking layers SL, SL′ and the photoresist layers RL, RL′ are removed to expose the sidewalls SW, SW′, the first conductive pillars 300, 300′, and the second conductive pillars 400, 400′. Next, as shown in FIG. 2O, the glue G and the base BL are removed to expose the upper surface US. In some embodiments, the glue G may be removed by a heating process.

Referring to FIG. 2P, an initial circuit board 100I is provided, and a stepped opening O is formed in the initial circuit board 100I. The initial circuit board 100I includes first connection wiring layers 102, 102′ and second connection wiring layers 104, 104′ exposed by the stepped opening O. In detail, the stepped opening O includes a bottom portion BP, a middle portion MP, and an opening portion OP. The middle portion MP is located between the bottom portion BP and the opening portion OP. The width of the opening portion OP is greater than the width of the middle portion MP, and the width of the middle portion MP is greater than the width of the bottom portion BP. In some embodiments, the stepped opening O may be formed by a laser process. The width W of the stepped opening O is about 500 micrometers to 1000 micrometers, and the depth T of the stepped opening O is about 100 micrometers to 150 micrometers. By forming the stepped opening O, the initial circuit board 100I can be recessed in different layers, so that the electronic component stacking structure 200 is completely attached to the initial circuit board 100I, thereby improving reliability.

Referring to FIG. 2Q, after the masking layers SL, SL′, the photoresist layers RL, RL′, the glue G, and the base BL are removed, the electronic component stacking structure 200, the first conductive pillars 300, 300′, and the second conductive pillars 400, 400′ are disposed in the stepped opening O, where the first conductive pillars 300, 300′ are electrically connected to the first connection wiring layers 102, 102′, and the second conductive pillars 400, 400′ are electrically connected to the second connection wiring layers 104, 104′. In detail, the bottom portion BP is used to accommodate the electronic component stacking structure 200, the middle portion MP is used to accommodate the electronic component stacking structure 200 and the first conductive pillars 300, 300′, and the opening portion OP is used to accommodate the electronic component stacking structure 200 and the second conductive pillars 400, 400′. The aforementioned design can limit the soldering range between the first electronic component 202 and the first connection wiring layers 102, 102′, and the soldering range between the second electronic component 204 and the second connection wiring layer 104, 104. The first electronic component 202 and the second electronic component 204 can form a stable electrical connection with the first connection wiring layers 102, 102′ and the second connection wiring layer 104, 104′, respectively, thereby improving reliability.

In addition, as shown in FIG. 2P and FIG. 2Q, before the electronic component stacking structure 200, the first conductive pillars 300, 300′, and the second conductive pillars 400, 400′ are disposed in the stepped opening O, solder balls (not labeled) are disposed on the first connection wiring layers 102, 102′ and the second connection wiring layers 104, 104′, respectively. The first conductive pillars 300, 300′ and the second conductive pillars 400, 400′ are electrically connected to the first connection wiring layers 102, 102′ and the second connection wiring layers 104, 104′ by the solder balls. By disposing the first conductive pillars 300, 300′ and the second conductive pillars 400, 400′ in the stepped opening O, the signal can directly reach the first connection wiring layer 102, 102′ and the second connection wiring layer 104, 104′, thereby reducing the fan-out area, reducing crosstalk between signals, and improving signal integrity.

Next, referring to FIG. 1, after the electronic component stacking structure 200, the first conductive pillars 300, 300′ and the second conductive pillars 400, 400′ are disposed in the stepped opening O, a build-up structure 500 is laminated to cover the stepped opening O, and a circuit board 100 is formed. In addition, a build-up structure 500′ is laminated on the side of the initial circuit board 100I opposite to the stepped opening O, and the build-up structures 500, 500′ are patterned to form conductive vias CV and wiring layers (not labeled) to form the circuit board 100.

In summary, in at least one embodiment of the circuit board assembly and its manufacturing method of the present disclosure, the electronic components of the electronic component stacking structure can be electrically connected to the connection wiring layers at different distances from the sidewall of the electronic component stacking structure by the conductive pillars, which have different lengths and are disposed on the sidewall. The fan-out space of the electronic components is reduced, thereby achieving the demand for miniaturization of the overall size of the circuit board assembly.

Although the present disclosure has been described in considerable details with reference to certain embodiments thereof, other embodiments are possible. Therefore, the spirit and scope of the appended claims should not be limited to the descriptions of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A method of manufacturing a circuit board assembly, comprising:
providing an electronic component stacking structure, wherein the electronic component stacking structure has a sidewall;
providing a base, wherein the base has a surface and a hole;
disposing the electronic component stacking structure in the hole;
after the electronic component stacking structure is disposed in the hole, attaching a photoresist layer to the surface;
forming a first opening and a second opening in the photoresist layer exposing the sidewall;
forming a first conductive pillar in the first opening and a first conductive portion in the second opening;
after the first conductive pillar and the first conductive portion are formed, forming a second conductive portion in the second opening connected to the first conductive portion to form a second conductive pillar, wherein the first conductive pillar and the second conductive pillar are connected to the sidewall, and a length of the second conductive pillar is greater than a length of the first conductive pillar;
providing an initial circuit board, wherein the initial circuit board has a stepped opening and comprises a first connection wiring layer and a second connection wiring layer; and
disposing the electronic component stacking structure, the first conductive pillar and the second conductive pillar in the stepped opening, wherein the first conductive pillar is electrically connected to the first connection wiring layer, and the second conductive pillar is electrically connected to the second connection wiring layer.

2. The method of manufacturing the circuit board assembly of claim 1, further comprising:
stacking and sealing a first electronic component, a second electronic component, and a third electronic component to form an initial electronic component stacking structure; and
polishing the initial electronic component stacking structure to form the electronic component stacking structure, wherein the first electronic component comprises a first pad exposed on the sidewall, the second electronic component comprises a second pad exposed on the sidewall, wherein the first conductive pillar and the second conductive pillar are connected to the first pad and the second pad, respectively.

3. The method of manufacturing the circuit board assembly of claim 1, wherein a step of forming the second conductive pillar comprises:
after the first conductive pillar and the first conductive portion are formed, attaching a masking layer to the first opening to cover the first opening; and
after the masking layer is attached to the first opening, forming the second conductive portion in the second opening, and the second conductive portion connected to the first conductive portion to form the second conductive pillar.

4. The method of manufacturing the circuit board assembly of claim 1, further comprising:
after the electronic component stacking structure, the first conductive pillar and the second conductive pillar are disposed in the stepped opening, laminating a build-up structure to cover the stepped opening to form a circuit board.

5. The method of manufacturing the circuit board assembly of claim 1, wherein the stepped opening comprises a bottom portion, a middle portion and an opening portion, the middle portion is located between the bottom portion and the opening portion, wherein a width of the opening portion is greater than a width of the middle portion, and a width of the middle portion is greater than a width of the bottom portion.

6. The method of manufacturing the circuit board assembly of claim 5, wherein the bottom portion is used to accommodate the electronic component stacking structure, the middle portion is used to accommodate the electronic component stacking structure and the first conductive pillar, and the opening portion is used to accommodate the electronic component stacking structure and the second conductive pillar.

7. The method of manufacturing the circuit board assembly of claim 1, further comprising:
before the electronic component stacking structure, the first conductive pillar and the second conductive pillar are disposed in the stepped opening, disposing a solder ball on the first connection wiring layer and the second connection wiring layer, respectively, wherein the first conductive pillar and the second conductive pillar are electrically connected to the first connection wiring layer and the second connection wiring layer through the solder balls, respectively.

8. A circuit board assembly, comprising:
a circuit board, comprising:
a first connection wiring layer; and
a second connection wiring layer, disposed on the first connection wiring layer;
an electronic component stacking structure, disposed in the circuit board, having a sidewall, and comprising:
a first electronic component, electrically connected to the first connection wiring layer; and
a second electronic component, disposed on the first electronic component and electrically connected to the second connection wiring layer;
a first conductive pillar, disposed on the sidewall, extending in a first direction away from the sidewall, and electrically connected to the first electronic component and the first connection wiring layer; and
a second conductive pillar, disposed on the sidewall, extending in the first direction, and electrically connected to the second electronic component and the second connection wiring layer,
wherein in the first direction, a distance between the first connection wiring layer and the sidewall is smaller than a distance between the second connection wiring layer and the sidewall, and a length of the first conductive pillar is smaller than a length of the second conductive pillar.

9. The circuit board assembly of claim 8, wherein the first electronic component comprises a first pad exposed on the sidewall, and the first conductive pillar is in contact with the first pad and disposed on the first connection wiring layer to electrically connect to the first electronic component and the first connection wiring layer.

10. The circuit board assembly of claim 8, wherein the second electronic component comprises a second pad exposed on the sidewall, and the second conductive pillar is in contact with the second pad and disposed on the second connection wiring layer to electrically connect to the second electronic component and the second connection wiring layer.

11. The circuit board assembly of claim 8, wherein the electronic component stacking structure has an upper surface, and comprises:
a third electronic component, disposed on the second electronic component and comprising a third pad, wherein the third pad is exposed on the upper surface.

12. The circuit board assembly of claim 11, wherein the circuit board further comprises:
a build-up structure, disposed on the third electronic component, and having a conductive via, wherein the conductive via is disposed on the third pad and electrically connected to the third pad.

13. The circuit board assembly of claim 8, wherein the second conductive pillar comprises a first conductive portion and a second conductive portion connecting to the first conductive portion, and a boundary exists between the first conductive portion and the second conductive portion.

14. The circuit board assembly of claim 8, wherein the second electronic component overlaps the first electronic component in a second direction perpendicular to the first direction, wherein the second connection wiring layer partially overlaps the first connection wiring layer in the second direction, and the second conductive pillar partially overlaps the first conductive pillar.

15. The circuit board assembly of claim 14, wherein an edge of the first electronic component and an edge of the second electronic component are flush with each other in the second direction.
